(19) United States
(12) Patent Application Publication
(10) Pub. No.: US 2013/0001602 A1
(43) Pub. Date: Jan. 3, 2013

(54) ORGANIC LIGHT EMITTING DEVICE, ORGANIC LIGHT EMITTING DISPLAY APPARATUS, AND METHODS OF MANUFACTURING THE SAME

(76) Inventors: Sang-IL PARK, Yongin-City (KR); Min-Kyu Kim, Yongin-City (KR); Chaun-Gi Choi, Yongin-City (KR); Kwang-Suk Kim, Yongin-City (KR)

(21) Appl. No.: 13/454,193

(22) Filed: Apr. 24, 2012

(30) Foreign Application Priority Data
Jun. 30, 2011 (KR) 10-2011-0065142

(51) Int. Cl. H01L 33/62

(52) U.S. Cl. 257/88; 257/99; 438/34; 977/773; 257/E33.062

(57) ABSTRACT

An organic light emitting display device includes a buffer layer on a substrate, the buffer layer including nano-particles, a pixel electrode on the buffer layer, an opposite electrode on the pixel electrode and facing the pixel electrode, and an organic emission layer between the pixel electrode and the opposite electrode.

### CROSS-REFERENCE TO RELATED PATENT APPLICATION

This application claims the benefit of Korean Patent Application No. 10-2011-0065142, filed on Jun. 30, 2011, in the Korean Intellectual Property Office, the disclosure of which is incorporated herein in its entirety by reference.

### BACKGROUND OF THE INVENTION

1. Field of the Invention

Embodiments relate to an organic light emitting device, an organic light emitting display apparatus, and a method of manufacturing the same.

2. Description of the Related Art

Organic light emitting display apparatuses may be driven with low voltage, may be thin, light in weight, may have wide viewing angles and excellent contrast, and fast response speeds, and thus, have been considered as next generation display apparatuses.

In organic light emitting display apparatuses, a voltage is applied between a positive electrode and a negative electrode so that electrons and holes recombine in an organic emission layer that is disposed between the positive and negative electrodes to generate excitons, which emit light as the excitons change from an excited state to a base state.

### SUMMARY OF THE INVENTION

An embodiment is directed to an organic light emitting device, including a buffer layer on a substrate, the buffer layer including nano-particles, a pixel electrode on the buffer layer, an opposite electrode on the pixel electrode and facing the pixel electrode, and an organic emission layer between the pixel electrode and the opposite electrode.

The buffer layer may include a first buffer layer on the substrate, a second buffer layer on the first buffer layer, and the nano-particles between the first buffer layer and the second buffer layer.

The nano-particles may include silver (Ag) or Ag—Pd—Cu (APC).

The buffer layer may further include a protective layer surrounding the nano-particles.

The protective layer may be a unitary body surrounding all of the nano-particles.

The protective layer may include a plurality of partitioned protective layers, each partitioned protective layer individually surrounding one or more different nano-particles.

The protective layer may include a plurality of partitioned protective layers, such that each of the partitioned protective layers surrounds groups of a plurality of the nano-particles.

The protective layer may include indium tin oxide (ITO) or indium zinc oxide (IZO).

Another embodiment is directed to an organic light emitting display apparatus, including a buffer layer on a substrate, the buffer layer including nano-particles, an organic light emitting device including a pixel electrode on a first area of the buffer layer, the pixel electrode including a transparent conductive material, an opposite electrode on the pixel electrode and facing the pixel electrode, and an organic emission layer between the pixel electrode and the opposite electrode, a thin film transistor including a gate electrode on a second area of the buffer layer, an active layer on the gate electrode and insulated from the gate electrode, and source and drain electrodes connected to two different regions of the active layer, such that one of the source and drain electrodes is connected to the pixel electrode, and a capacitor including lower electrodes on a third area of the buffer layer, an upper electrode on the third area of the buffer layer and facing the lower electrodes, and a dielectric layer disposed between the lower electrodes and the upper electrode.

The nano-particles may be on the first area of the buffer layer.

The nano-particles may be on an entire area of the buffer layer.

The buffer layer may include a first buffer layer on the substrate, a second buffer layer on the first buffer layer, and the nano-particles between the first buffer layer and the second buffer layer.

The nano-particles may include silver (Ag) or Ag—Pd—Cu (APC).

The buffer layer may further include a protective layer surrounding the nano-particles.

The protective layer may be a unitary body surrounding all the nano-particles.

The protective layer may include a plurality of partitioned protective layers, each of the partitioned protective layers individually surrounding one or more different ones of the nano-particles.

The protective layer may include a plurality of partitioned protective layers, each of the partitioned protective layers surrounding groups of a plurality of the nano-particles.

The protective layer may include indium tin oxide (ITO) or indium zinc oxide (IZO).

Another embodiment is directed to a method of manufacturing an organic light emitting display apparatus, the method including forming a buffer layer including nano-particles on a substrate, performing a first mask process for forming a pixel electrode and a metal layer on a first area of the buffer layer, the pixel electrode including a transparent conductive material and the metal layer including a lower resistive metal material, a first gate electrode of a thin film transistor and a second gate electrode of a thin film transistor on a second area of the buffer, the first gate electrode including a material that is the same as that of the pixel electrode and the second gate electrode including a material that is the same as that of the metal layer, and a first lower electrode of a capacitor and a second lower electrode of a capacitor on a third area of the buffer layer, the first lower electrode of a capacitor including a material that is the same as that of the first gate electrode and the second lower electrode of a capacitor including a material that is the same as that of the second gate electrode, performing a second mask process for forming a first insulating layer that covers the metal layer, the second gate electrode, and the second lower electrode, and an active layer of the thin film transistor on the first insulation layer, the active layer including a transparent conductive oxide semiconductor, performing a third mask process for forming a second insulating layer on the first insulating layer for covering the active layer, contact holes through the second insulating layer for exposing two regions of the active layer, and a via-hole through the first and second insulating layers for exposing a part of the metal layer, performing a fourth mask process for simultaneously forming an opening for exposing the pixel electrode, source and drain electrodes covering the contact holes and the via-hole, and an upper electrode of the capacitor, performing a fifth mask process for forming a third insulating layer covering the source and drain electrodes, an opening in the third insulating layer to expose the pixel electrode, and forming an emission layer including an opposite electrode facing the pixel electrode, and an organic emission layer between the pixel electrode and the opposite electrode.

Forming of the buffer layer may include forming a first buffer layer on the substrate, forming the nano-particles on the first buffer layer, and forming a second buffer layer on the nano-particles.

The method may further include forming a protective layer on the nano-particles, after forming the nano-particles.

The protective layer may be formed as a unitary body to surround all the nano-particles.

The protective layer may be partitioned to form a plurality of partitioned protective layers independently surrounding one or more of the nano-particles.

The protective layer may be partitioned to form a plurality of partitioned protective layers independently surrounding groups of a plurality of the nano-particles.

### BRIEF DESCRIPTION OF THE DRAWINGS

The above and other features and advantages of the embodiments will become more apparent by describing in detail exemplary embodiments thereof with reference to the attached drawings in which:

FIG. 1 illustrates a schematic cross-sectional view of an organic light emitting display apparatus according to an embodiment;

FIGS. 2 through 4 illustrate cross-sectional views of modified examples of a region A shown in FIG. 1; and

FIGS. 5 through 13 illustrate cross-sectional views sequentially of stages in a method of manufacturing the organic light emitting display apparatus of FIG. 1, according to an embodiment.

### DETAILED DESCRIPTION OF THE INVENTION

Hereinafter, embodiments of an organic light emitting display apparatus will be described with reference to accompanying drawings.

FIG. 1 illustrates a schematic cross-sectional view of an organic light emitting display apparatus 1 according to an embodiment.

Referring to FIG. 1, the organic light emitting display apparatus 1 may include a first area 100 including a buffer layer 20 that includes nano-particles 25 formed on a substrate 10 and a light emission unit formed on the buffer layer 20; a second area 200 including a thin film transistor (TFT); and a third area 300 including a capacitor.

The substrate 10 may be formed of a transparent glass material, mainly including SiO₂. However, the substrate 10 of the present embodiment is not limited thereto, and may be formed of various materials such as, for example, transparent plastic material.

The buffer layer 20 may be disposed on the substrate 10. The buffer layer 20 may include SiO₂ and/or SiN_{X} to planarize the substrate 10 and prevent impurities from infiltrating into the buffer layer 20.

The buffer layer 20 may include the nano-particles 25 therein. The nano-particles may include silver (Ag) or Ag—Pd—Cu (APC). The buffer layer 20 including the nano-particles 25 may function as a transflective mirror layer of an organic light emitting device.

In more detail, the buffer layer 20 may include a first buffer layer 21, a second buffer layer 22, and the nano-particles 25 between the first and second buffer layers 21 and 22. The first and second buffer layers 21 and 22 may include materials that are the same or different from each other.

The nano-particles 25 may be formed by an annealing process of a layer having a nano-thickness and may include Ag. After forming the nano-particles 25, the second buffer layer 22 may cover the nano-particles 25.

The nano-particles 25 may be formed only on the first buffer layer 21, e.g., on the entire first buffer layer 21 or on a portion of the first buffer layer 21 corresponding to the first area 100, that may be a pixel region.

When the nano-particles 25, functioning as the transflective mirror, are formed on the buffer layer 20, an external resonant structure may be formed of an opposite electrode 106 functioning as a reflective mirror. Thus, a light extracting efficiency of the organic light emitting display apparatus 1 may be improved. In addition, the above structure of the buffer layer 20 including the nano-particles 25 may be fabricated by a separate process from a process of forming a pixel electrode 101 described below. Therefore, damage to the nano-particles 25, which may result by an etching of the pixel electrode 101, and damage to the transflective mirror may be prevented. Thus, no damage may result to the resonant structure of the organic light emitting device during the fabrication processes.

The pixel electrode 101 including a transparent conductive material may be disposed on the first area 100 of the buffer layer 20. The pixel electrode 101 may include at least one or more materials selected from indium tin oxide (ITO), indium zinc oxide (IZO), zinc oxide (ZnO), indium oxide (In₂O₃), indium gallium oxide (IGO), and aluminum zinc oxide (AZO).

A metal layer 102, formed of a low resistive metal material that is the same as a material included in a second gate electrode 202 described below, may be further formed on an upper edge portion of the pixel electrode 101.

A first insulating layer 30 and a second insulating layer 40 may be sequentially stacked on the pixel electrode 101 and the metal layer 102, and an opening C1 for exposing the pixel electrode 101 may be formed on the stacked metal layer 102, the first insulating layer 30, and the second insulating layer 40. In addition, a via-hole C2 may be formed in the first and second insulating layers 30 and 40. The via-hole C2 may function as a path for connecting source and drain electrodes 204a and 204b of the TFT to the metal layer 102 as described below.

A third insulating layer 50 may be formed on the second insulating layer 40, and an opening C4 for exposing the pixel electrode 101 may be formed in the third insulating layer 50.

An emission layer 105 may be formed on the pixel electrode 101 exposed in the opening C4 of the third insulating layer 50, and light emitted from the emission layer 105 may be emitted toward the substrate 10 through the pixel electrode 101 that may be formed of the transparent conductive material.

The emission layer 105 may be formed of a low-molecular weight organic material or a high-molecular weight organic material. When a low-molecular weight organic material is used, the emission layer 105 may have a multi-layer structure, including at least one selected from a hole injection layer (HIL), a hole transport layer (HTL), an electron transport layer (ETL), and an electron injection layer (EIL). Examples of available organic materials may include copper phthalocyanine (CuPc), N,N′-di(naphthalene-1-yl)-N,N′-diphenyl-benzidine (NPB), tris-8-hydroxyquinoline aluminum (Alq3), and the like. On the other hand, when a high-molecular weight organic layer is used, the emission layer 105 may have a structure at least including a HTL. The HTL may include poly(ethylenedioxythiophene) (PEDOT) or polyaniline (PANI). The high-molecular weight organic material that may be used may be a polymer organic material, e.g., polyphenylenevinylenes (PPVs) or polyfluorenes.

An opposite electrode 106 may be disposed on the emission layer 105 as a common electrode. In the organic light emitting display apparatus 1 according to the present embodiment, the pixel electrode 101 may be used as an anode and the opposite electrode 106 may be used as a cathode. Alternatively, according to some embodiments, the pixel electrode 101 may be used as a cathode and the opposite electrode 106 may be used as an anode.

The opposite electrode 106 may be formed as a reflective electrode including a reflective material. The opposite electrode 106 may include one or more materials from the group of Al, Mg, Li, Ca, LiF/Ca, and LiF/Al. The opposite electrode 106 may be a reflective electrode. As such, light emitted from the emission layer 105 may be reflected by the opposite electrode 106 and then transmitted through the pixel electrode 101 formed of the transparent conductive material, to be emitted toward the substrate 10. The nano-particles 25, formed of Ag, in the buffer layer 20 may function as the transflective mirror. Thus, an external resonant structure may be formed, and the light extracting efficiency of the organic light emitting display apparatus 1 may be improved.

A first gate electrode 201 and the second gate electrode 202, both of which may be formed of the same material as the pixel electrode 101 and the metal layer, may be formed on the second area 200 on the buffer layer 20. The first insulating layer 30, functioning as the gate insulating layer, may be disposed on the second gate electrode 202. An active layer 203 may be disposed on the first insulating layer 30.

The second gate electrode 202 may be formed at the same level as the metal layer 102, and from the same low resistive metal material as the metal layer 102.

The first insulating layer 30 may be disposed on the second gate electrode 202, and the active layer 203 of the TFT may be disposed on the first insulating layer 30.

The active layer 203 may include a transparent conductive oxide semiconductor.

The transparent conductive oxide semiconductor may include one or more materials from the group of gallium (Ga), indium (In), zinc (Zn), and tin (Sn). For example, the transparent conductive oxide semiconductor material may be one selected from InGaZnO, ZnSnO, InZnO, InGaO, ZnO, TiO, and hafnium-indium-zinc oxide (HIZO). The oxide semiconductor TFT including the transparent conductive oxide semiconductor material as the active layer 203 may have excellent device characteristics, and may be used to perform processes at a low temperature. In addition, the oxide semiconductor TFT may be transparent and flexible in the visible rays band. Thus, the oxide semiconductor TFT may be applied to a transparent display apparatus or a flexible display apparatus.

The second insulating layer 40 may cover the active layer 203, and the source and drain electrodes 204a and 204b that are connected to two regions respectively of the active layer 203 via contact holes C3 through the second insulating layer 40, may be disposed on the second insulating layer 40. In addition, one of the source and drain electrodes 204a and 204b may be connected to the metal layer 102 on the pixel electrode 101 of the first area 100 via the via-hole C2 through both the first and second insulating layers 30 and 40.

The third insulating layer 50 may be disposed on the source and drain electrodes 204a and 204b.

The third area 300 of the buffer layer 20 may be a capacitor area on which first and second lower electrodes 301 and 302 and an upper electrode 304 of the capacitor may be disposed, with the first and second insulating layers 30 and 40 between the first and second lower electrodes 301 and 302 and the upper electrode 304.

The first lower electrode 301 of the capacitor may include the same material as those of the pixel electrode 101 and the first gate electrode 201, and may be at the same layer level as the pixel electrode 101 and the first gate electrode 201. The second lower electrode 302 of the capacitor may be formed of the same material as that of the second gate electrode 202, and may be at the same layer level as the second gate electrode 202. The first and second insulating layers 30 and 40 may function as dielectric layers of the capacitor. In the present embodiment, the first and second lower electrodes 301 and 302 may be formed in the same mask processes as the pixel electrode 101, the metal layer 102, the first gate electrode 201, and the second gate electrode 202. Thus, fabrication processes may become simplified.

The first and second insulating layers 30 and 40 may be sequentially stacked on the second lower electrode 302 of the capacitor. The upper electrode 304 may include the same material as that of the source and drain electrodes 204a and 204b, and may be at the same layer level as the source and drain electrodes 204a and 204b.

The third insulating layer 50 may cover the upper electrode 304, and the opening C4, exposing the pixel electrode 101, may be formed in the third insulating layer 50, as described above.

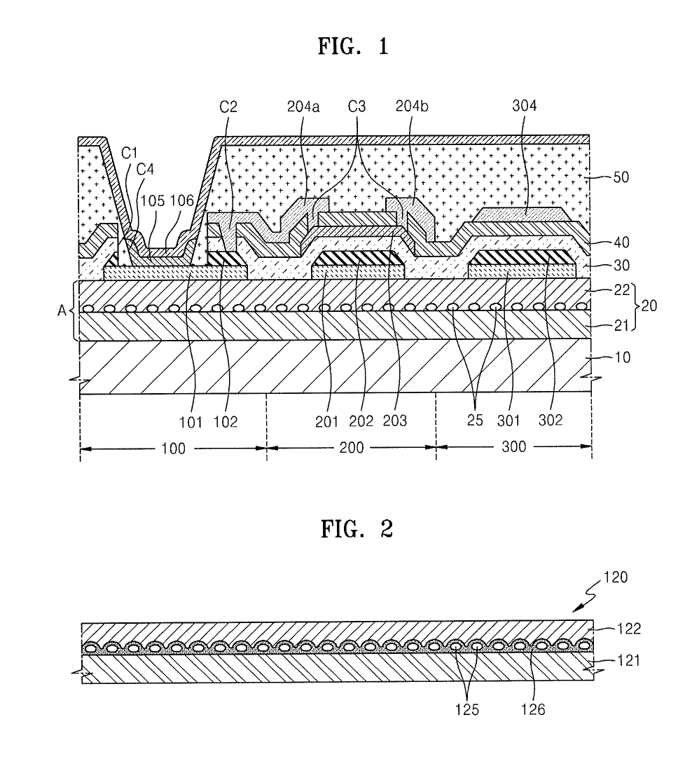

FIGS. 2 through 4 illustrate schematic cross-sectional views of modified examples of a part A shown in FIG. 1.

Referring to FIG. 2, a protective layer 126, surrounding the nano-particles 125, may be disposed between a first buffer layer 121 and a second buffer layer 122.

The protective layer 126 may include a transparent conductive material, for example, ITO, IZO, ZnO, In₂O₃, IGO, or AZO.

The nano-particles 125 may be formed on the first buffer layer 121, and the protective layer 126 may cover the nano-particles 125 in a chemical vapor deposition (CVD) or a sputtering method. After that, the second buffer layer 122 may cover the protective layer 126.

The protective layer 126 may be formed integrally to surround all of the nano-particles 125.

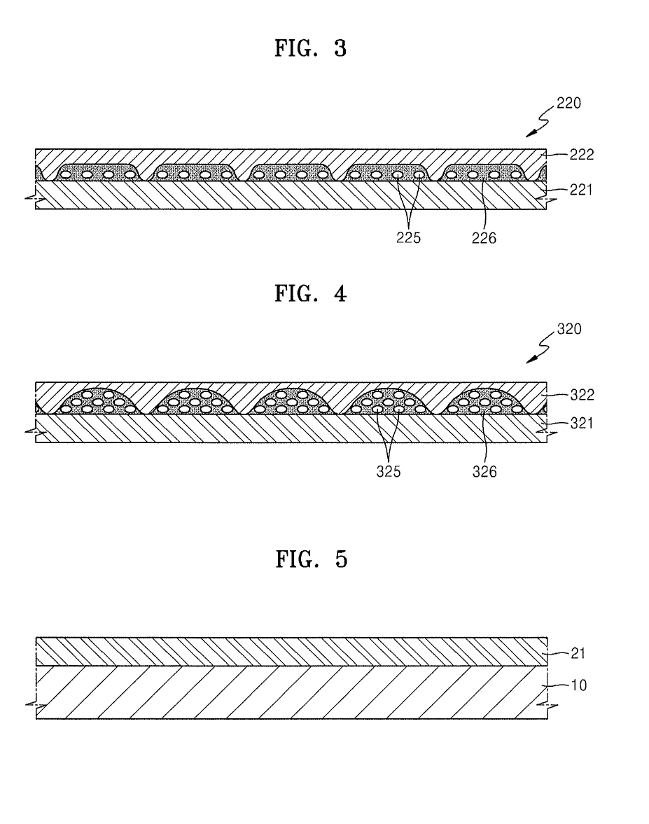

FIG. 3 illustrates a structure that is the same as that of FIG. 2, except for a protective layer 226.

Nano-particles 225 may be formed on a first buffer layer 221, and the protective layer 226, covering the nano-particles 225, may be formed. In addition, a second buffer layer 222 may cover the protective layer 226. The protective layer 226 may be partitioned into a plurality of partitioned protective layers 226. The partitioned protective layers 226 may include depressions or gaps therebetween, through which the first and second buffer layers 221 and 222 may contact each other. Each partitioned protective layer 226 may cover one or more different nanoparticles 225.

In each of the partitioned protective layers 226, nano-particles 225 may be included; however, the number of nano-particles 225 included in each partition may not be defined.

The number of nano-particles 225 included in each of the partitioned protective layers 226 may be different. In addition, one nano-particle may be included in one partitioned protective layer 226.

FIG. 4 illustrates a structure that is the same as that of FIG. 3, except that nano-particles 325 included in each of partitioned protective layers 326 are not arranged in a row, but in a plurality of rows to form a group.

FIGS. 5 through 13 illustrate cross-sectional views sequentially of stages in a method of manufacturing the organic light emitting display apparatus 1, according to an embodiment.

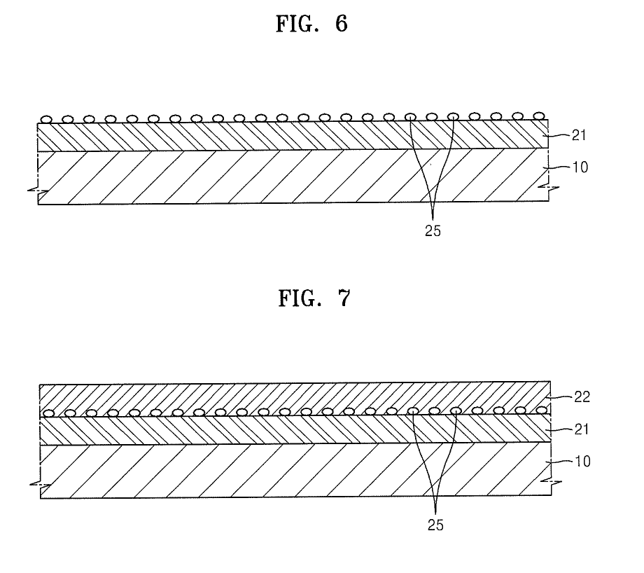

Referring to FIGS. 5 and 6, the first buffer layer 21 may be formed on the substrate 10, and the nano-particles 25 may be formed on the first buffer layer 21.

The nano-particles 25 may be formed by depositing a layer of a nano-thickness on the first buffer layer 21 and annealing the nano-layer.

Referring to FIG. 7, the second buffer layer 22 may be formed on the first buffer layer 21 to cover the nano-particles 25.

As described above, after forming the nano-particles 25, the protective layer 126, 226, or 326 may be formed by a CVD method or a sputtering method.

In order to partition the protective layer 226 or 326 as shown in FIG. 3 or FIG. 4, the protective layer 226 or 326 may be formed entirely on the buffer layer 22, and then the protective layer 226 or 326 may be patterned by a photolithography method.

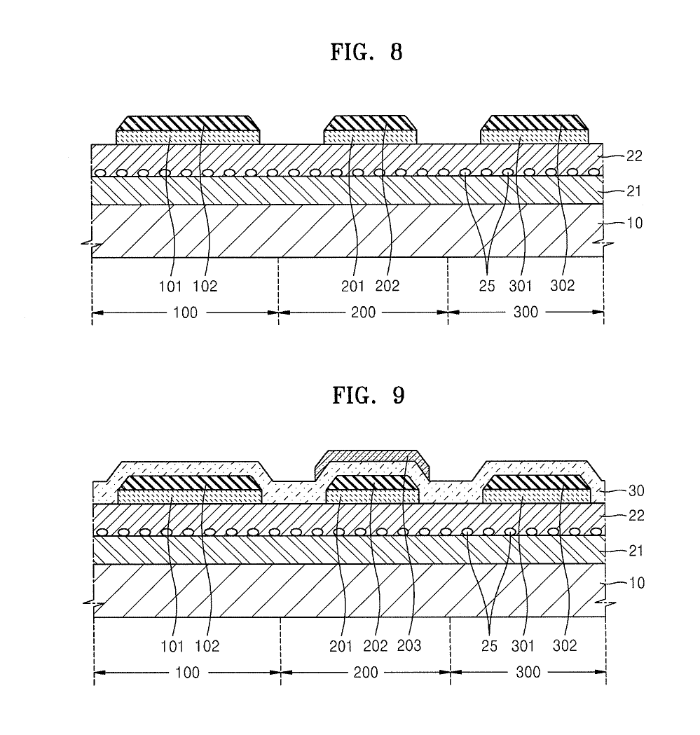

FIG. 8 illustrates a schematic cross-sectional view of a result of a first mask process in the fabrication method of the organic light emitting display apparatus 1 shown in FIG. 1.

Referring to FIG. 8, the pixel electrode 101 and the metal layer 102 on the first area 100, the first gate electrode 201 and the second gate electrode 202 on the second area 200, and the first lower electrode 301 and the second lower electrode 302 of the capacitor on the third area 300 may be simultaneously formed through the same mask process on the buffer layer 20.

Although the fabrication processes are not shown in detail in FIG. 8, the transparent conductive material and the low resistive metal material may be deposited sequentially on the buffer layer 20, and photoresist (not shown) may be applied thereon. Then, a photolithography process using a first mask (not shown) may be performed to pattern the pixel electrode 101, the metal layer 102, the first gate electrode 201, the second gate electrode 202, the first lower electrode 301, and the second lower electrode 302 simultaneously. The first mask process of the photolithography may include a series of processes, such as an exposure of the first mask (not shown) by using an exposure device (not shown), developing, etching, and stripping, or ashing processes. Hereinafter, the above described processes will not be repeated in the description of the subsequent mask processes.

FIG. 9 illustrates a schematic cross-sectional view showing a result of a second mask process for manufacturing the organic light emitting display apparatus 1 of FIG. 1.

The first insulating layer 30 may be formed on the resultant of the first mask process, and the active layer 203 may be formed on the first insulating layer 30. The active layer 203 may include the transparent conductive oxide semiconductor as described above.

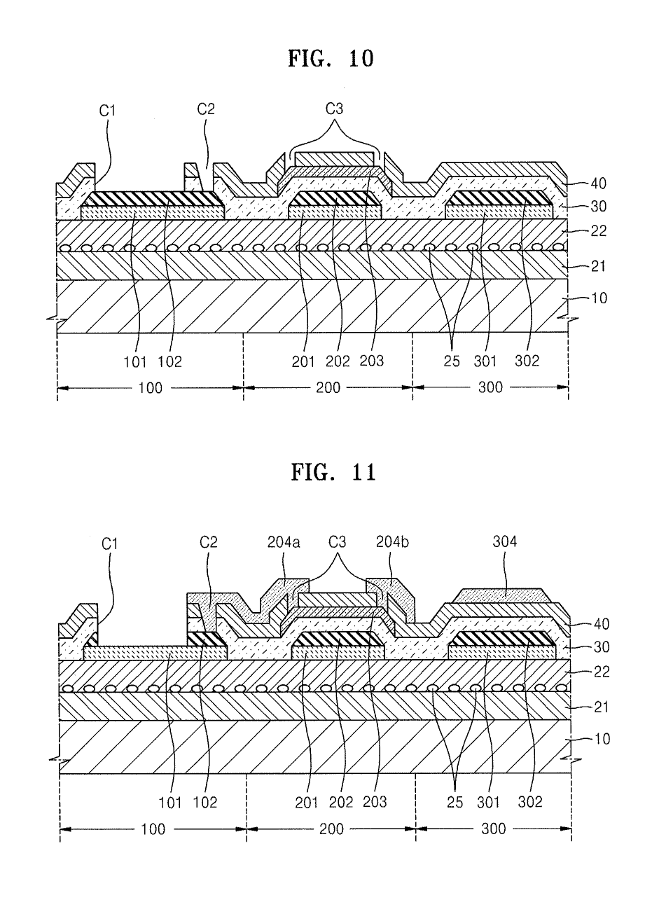

FIG. 10 illustrates a schematic cross-sectional view of the resultant of a third mask process for manufacturing the organic light emitting display apparatus 1 of FIG. 1.

The second insulating layer 40 may be formed on the resultant of the second mask process, and the via-hole C2 and the contact holes C3 may be formed in the second insulating layer 40 through the third mask process. A portion of the first and second insulating layers 30 and 40, corresponding to an upper portion of the pixel electrode 101, may be removed to form the opening C1 that exposes an upper surface of the metal layer 102. The metal layer 102 may not be removed and may remain on the pixel electrode 101.

FIG. 11 illustrates a schematic cross-sectional view showing a result of a fourth mask process for manufacturing the organic light emitting display apparatus 1 of FIG. 1.

A layer (not shown) including the material for forming source and drain electrodes may be formed on the resultant of the third mask process so as to cover the opening C1, the via-hole C2, and the contact holes C3. A photolithography process may be performed to form the source and drain electrodes 204a and 204b of the TFT and the upper electrode 304 of the capacitor. The metal layer 102 on the pixel electrode 101 may be simultaneously etched through the etching process which etches the source and drain electrodes.

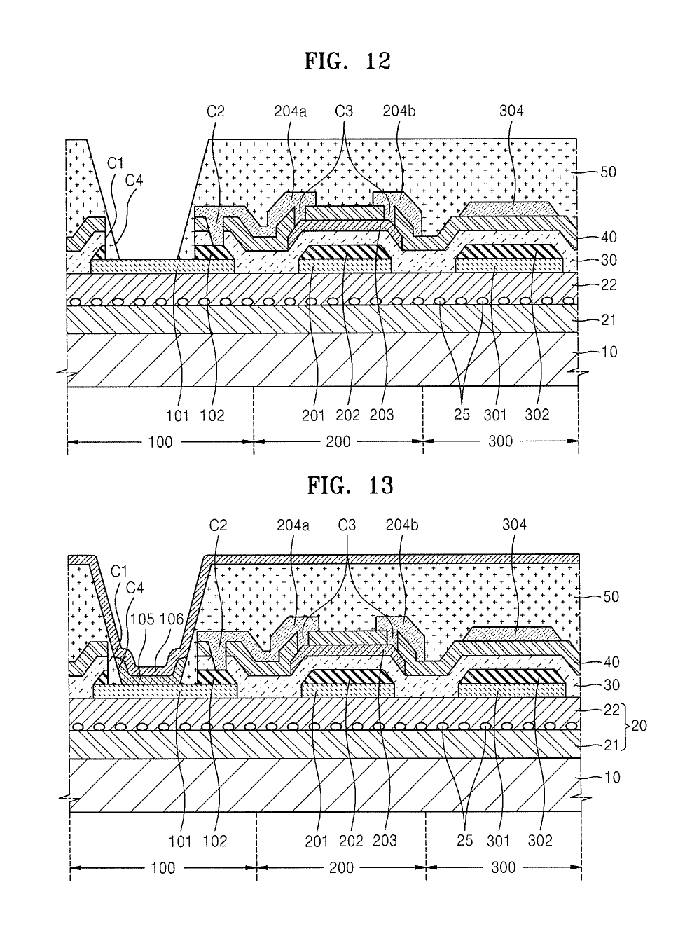

FIG. 12 may be a schematic cross-sectional view showing a result of a fifth mask process for manufacturing the organic light emitting display apparatus 1 of FIG. 1.

The third insulating layer 50 may be formed on the resultant of the fourth mask process, and a part of the third insulating layer 50 may be removed to form the opening C4 exposing the upper surface of the pixel electrode 101.

Referring to FIG. 13, the emission layer 105 and the opposite electrode 106 may be formed on the pixel electrode 101 exposed through the opening C4 that is formed in the fifth mask process.

For manufacturing an organic light emitting display apparatus including a bottom gate type oxide semiconductor according to embodiments, the mask processes may be performed five times. In other words, the buffer layer 20 including the nano-particles 25 functioning as the transflective mirror in the resonant structure may be formed without performing an additional mask process. Thus, a resonant structure may be formed without performing an additional mask process. Accordingly, fabrication costs may be sharply reduced.

By way of summation and review, a organic light emitting display apparatus has a wide light emission wavelength, and accordingly, light emission efficiency thereof may be reduced and a color purity thereof may be degraded. In addition, light emitted from the organic emission layer without directionality may emit a lot of photons in arbitrary directions, such that they may not reach an actual viewer due to total internal reflection of the organic light emitting device. Therefore, light extracting efficiency of the organic light emitting device may be degraded. Therefore, a method of improving the color purity by using a distributed Bragg reflector (DBR) mirror in the organic light emitting display apparatus or adjusting a thickness of the organic emission layer may be be considered. However, fabrication processes become complex when the DBR mirror is introduced, the viewing angle may be narrowed, and display characteristics may be degraded. In addition, in adjusting a thickness of an organic emission layer, electric characteristics of the organic light emitting display apparatus are degraded.

In contrast, an organic light emitting device, an organic light emitting display apparatus, and a fabrication method according to embodiments may provide an improved external resonant structure. The improved resonant structure may not be damaged during the fabrication processes and the light emitting efficiency of the organic light emitting display apparatus may be improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting device, comprising:
a buffer layer on a substrate, the buffer layer including nano-particles;
a pixel electrode on the buffer layer;
an opposite electrode on the pixel electrode and facing the pixel electrode; and
an organic emission layer between the pixel electrode and the opposite electrode.

2. The organic light emitting device of claim 1, wherein the buffer layer includes:
a first buffer layer on the substrate;
a second buffer layer on the first buffer layer; and
the nano-particles between the first buffer layer and the second buffer layer.

3. The organic light emitting device of claim 1, wherein the nano-particles include silver (Ag) or Ag—Pd—Cu (APC).

4. The organic device of claim 1, wherein the buffer layer further includes a protective layer surrounding the nano-particles.

5. The organic light emitting device of claim 4, wherein the protective layer is a unitary body surrounding all of the nano-particles.

6. The organic light emitting device of claim 4, wherein the protective layer includes a plurality of partitioned protective layers, each partitioned protective layer individually surrounding one or more different nano-particles.

7. The organic light emitting device of claim 4, wherein the protective layer includes a plurality of partitioned protective layers, such that each of the partitioned protective layers surrounds groups of a plurality of the nano-particles.

8. The organic light emitting device of claim 4, wherein the protective layer includes indium tin oxide (ITO) or indium zinc oxide (IZO).

9. An organic light emitting display apparatus, comprising:
a buffer layer on a substrate, the buffer layer including nano-particles;
an organic light emitting device including:
a pixel electrode on a first area of the buffer layer, the pixel electrode including a transparent conductive material;
an opposite electrode on the pixel electrode and facing the pixel electrode; and
an organic emission layer between the pixel electrode and the opposite electrode;
a thin film transistor including:
a gate electrode on a second area of the buffer layer;
an active layer on the gate electrode and insulated from the gate electrode; and
source and drain electrodes connected to two different regions of the active layer, such that one of the source and drain electrodes is connected to the pixel electrode; and
a capacitor including:
lower electrodes on a third area of the buffer layer;
an upper electrode on the third area of the buffer layer and facing the lower electrodes; and
a dielectric layer disposed between the lower electrodes and the upper electrode.

10. The organic light emitting display apparatus of claim 9, wherein the nano-particles are on the first area of the buffer layer.

11. The organic light emitting display apparatus of claim 9, wherein the nano-particles are on an entire area of the buffer layer.

12. The organic light emitting display apparatus of claim 9, wherein the buffer layer includes:
a first buffer layer on the substrate;
a second buffer layer on the first buffer layer; and
the nano-particles between the first buffer layer and the second buffer layer.

13. The organic light emitting display apparatus of claim 9, wherein the nano-particles include silver (Ag) or Ag—Pd—Cu (APC).

14. The organic light emitting display apparatus of claim 9, wherein the buffer layer further includes a protective layer surrounding the nano-particles.

15. The organic light emitting display apparatus of claim 14, wherein the protective layer is a unitary body surrounding all the nano-particles.

16. The organic light emitting display apparatus of claim 14, wherein the protective layer includes a plurality of partitioned protective layers, each of the partitioned protective layers individually surrounding one or more different ones of the nano-particles.

17. The organic light emitting display apparatus of claim 14, wherein the protective layer includes a plurality of partitioned protective layers, each of the partitioned protective layers surrounding groups of a plurality of the nano-particles.

18. The organic light emitting display apparatus of claim 14, wherein the protective layer includes indium tin oxide (ITO) or indium zinc oxide (IZO).

19. A method of manufacturing an organic light emitting display apparatus, the method comprising:
forming a buffer layer including nano-particles on a substrate;
performing a first mask process for forming:
a pixel electrode and a metal layer on a first area of the buffer layer, the pixel electrode including a transparent conductive material and the metal layer including a lower resistive metal material,
a first gate electrode of a thin film transistor and a second gate electrode of a thin film transistor on a second area of the buffer, the first gate electrode including a material that is the same as that of the pixel electrode and the second gate electrode including a material that is the same as that of the metal layer, and
a first lower electrode of a capacitor and a second lower electrode of a capacitor on a third area of the buffer layer, the first lower electrode including a material that is the same as that of the first gate electrode and the second lower electrode including a material that is the same as that of the second gate electrode;
performing a second mask process for forming:
a first insulating layer that covers the metal layer, the second gate electrode, and the second lower electrode, and
an active layer of the thin film transistor on the first insulation layer, the active layer including a transparent conductive oxide semiconductor;
performing a third mask process for forming:
a second insulating layer on the first insulating layer for covering the active layer,
contact holes through the second insulating layer for exposing two regions of the active layer, and
a via-hole through the first and second insulating layers for exposing a part of the metal layer;
performing a fourth mask process for simultaneously forming:
an opening for exposing the pixel electrode,
source and drain electrodes covering the contact holes and the via-hole, and
an upper electrode of the capacitor;
performing a fifth mask process for forming:
a third insulating layer covering the source and drain electrodes,
an opening in the third insulating layer to expose the pixel electrode; and
forming an emission layer including an opposite electrode facing the pixel electrode, and an organic emission layer between the pixel electrode and the opposite electrode.

20. The method of claim 19, wherein forming of the buffer layer includes:
forming a first buffer layer on the substrate;
forming the nano-particles on the first buffer layer; and
forming a second buffer layer on the nano-particles.

21. The method of claim 20, further comprising forming a protective layer on the nano-particles, after forming the nano-particles.

22. The method of claim 21, wherein the protective layer is formed as a unitary body to surround all the nano-particles.

23. The method of claim 21, wherein the protective layer is partitioned to form a plurality of partitioned protective layers independently surrounding one or more of the nano-particles.

24. The method of claim 21, wherein the protective layer is partitioned to form a plurality of partitioned protective layers independently surrounding groups of a plurality of the nano-particles.
